(19) United States
(12) Patent Application Publication
(10) Pub. No.: US 2017/0291819 A1
(43) Pub. Date: Oct. 12, 2017

(54) THREE-DIMENSIONAL POLYHEDRAL MICROSCALE GRAPHENE-BASED STRUCTURES AND METHODS OF MANUFACTURE

(71) Applicant: Regents of the University of Minnesota, Minneapolis, MN (US)

(72) Inventors: Jeong-Hyun Cho, Woodbury, MN (US); Daeha Joung, Minneapolis, MN (US)

(73) Assignee: Regents of the University of Minnesota, Minneapolis, MN (US)

(21) Appl. No.: 15/482,383

(22) Filed: Apr. 7, 2017

Related U.S. Application Data
(60) Provisional application No. 62/320,091, filed on Apr. 8, 2016.

(51) Int. Cl. C01B 31/02; G03F 7/20; B29C 67/00

(52) U.S. Cl. CPC C01B 31/043; G03F 7/70; B82Y 40/00

(57) ABSTRACT

Methods of making a microscale, free-standing, 3D, polyhedral, hollow, GO (or other graphene-based) structure using an origami-like self-folding approach. The origami-like self-folding process allows for easy control of size, shape, and thickness of graphene-based membranes, which, in turn, permits fabrication of freestanding 3D microscale polyhedral GO structures for example. With the 3D GO, a novel optical switching behavior is created, resulting from a combination of the geometrical effect of the 3D hollow structure and the water-permeable multi-layered GO membrane that affect the optical paths.

### CROSS-REFERENCE TO RELATED APPLICATIONS

This Non-Provisional Patent Application claims the benefit of the filing date of U.S. Provisional Patent Application Ser. No. 62/320,091, filed Apr. 8, 2016, entitled “Three-Dimensional Polyhedral Microscale Graphene-Based Structures and Methods of Manufacture,” the entire teachings of which are incorporated herein by reference.

### BACKGROUND

Two-dimensional (“2D”) materials, such as graphene, graphene oxide (“GO”), transition metal dichalcogenides (“TMDC”s) and black phosphorus, possess extraordinary electronic, optical, mechanical, and permeation properties, making them model systems for the observation of a novel physical phenomenon and building blocks for future devices. The assembly of the 2D materials into three-dimensional (“3D”) structures without sacrificing their intrinsic properties has been of great interest in the last few years because 3D structures provide insights into 2D material capability and design. Unlike other 2D materials, oxygen functional groups in GO especially allow the formation of multi-layered (laminate) structures and provide opportunities for tailoring its chemical functionality, offering tunable electrical, optical, and electrochemical properties. This unique structure also permits tunable interlayer space by surface modification and can be strongly influenced by the surrounding environments. If the tunable properties of 2D GO materials can be applied to free-standing 3D structures by realizing 3D GO, the 3D structures can embody new physical and chemical properties, which are otherwise difficult to observe in 2D GO materials defined on planar substrates.

In order to realize 3D GO structures, a number of synthetic methods, i.e., template-assisted assembly, flow-directed assembly, leavening assembly, and 3D printing methods, have been introduced in recent years. However, the sizes of 3D structures prepared by these synthetic methods are not easily controlled, and the shapes of the structures are just periodic, randomly cross-linked, continuous, GO sheets like 3D sponge structures. In addition, their complicated 3D networks do not allow for the formation of hollow structures with enough encapsulated space for certain purposes such as chemical or biological storage. Such methods also require strong chemical reactions with surfactants that affect the intrinsic properties of GO. This limits applications to only devices requiring large surface areas such as chemical sensors, electrode materials in energy storage systems, catalysts, and environmental remediation. Although it is known that using well-controlled, free-standing, hollow, 3D graphene-based structures, such as 3D polyhedral graphene, will open new opportunities for diverse applications, it is extremely challenging to construct the free-standing, hollow, 3D, polyhedral, graphene-based materials without sacrificing the novel properties of the 2D materials, especially in micro and nanoscale.

### SUMMARY

The present disclosure addresses one or more of the above concerns.

Some aspects of the present disclosure are directed toward methods of making a microscale, free-standing, 3D, polyhedral, hollow, GO (or other graphene-based) structure using an origami-like self-folding approach. This approach allows for the fabrication of a 3D structure with both vertical and horizontal free-standing graphene-based 2D material that does not require additional support or substrate. The methods of the present disclosure overcome the foremost challenge of controllable fabrication of 3D cubic structures with both vertical and horizontal free-standing GO. The 3D GO structures are created in a way that allows retention of the GO's intrinsic properties.

Other aspects of the present disclosure are directed toward 3D graphene-based microstructures with tunable optical properties. The 3D microstructures of the present disclosure exhibit dynamic physical or chemical tuning of the 3D GO as new material properties that are not observable in 2D GO. Moreover, the 3D structures of the present disclosure are free-standing and hollow, which means gases and/or liquids can be stored within or allowed light to pass through this 3D structure (multiple faces) given that the structure is optionally built with permeable GO membranes. Using this 3D, free-standing, hollow, GO-based cube configured with multi-layered, 2D, GO membranes, the optical transparency changes of the membranes can be dynamically tuned (e.g., by tuning the physical structure of the membranes (gap between GO layers)). In some embodiments, when the hollow, 3D, GO structure is wet by water, the 3D structure is transparent; when the water is dried out, the 3D structure becomes opaque. This tunable optical response is both repeatable and reversible. However, interestingly, such dramatic transparency changes have not been observed in a 2D GO structure and a 3D aluminum oxide (Al₂O₃) structure, which indicates that the tunable optical transparency effect is produced by a combination of permeation-driven tunable properties from multilayer GO structures and 3D geometrical effects.

As used throughout the present disclosure, the term “graphene-based” is in reference to graphene or graphene oxide (“GO”). Unless specifically stated, reference to “graphene oxide” or “GO” is inclusive of other graphene-based materials.

### BRIEF DESCRIPTION OF THE DRAWINGS

FIG. 1A is a simplified perspective view of a 2D net of graphene-based micropanels useful in forming a 3D graphene-based microstructure in accordance with principles of the present disclosure;

FIG. 1B schematically illustrates methods of the present disclosure;

FIG. 1C is a simplified perspective view of a 3D graphene-based microstructure resulting from the 2D net of FIG. 1A;

FIG. 2A is a plot and schematic illustration of water interfacing with a membrane useful with the present disclosure and comprising a plurality of GO layers;

FIG. 2B is a schematic, cross-section illustration of reflection and refraction of light in and on a hollow 3D structure;

FIG. 2C is a schematic, perspective illustration of reflection and refraction of light in and on a hollow 3D structure;

FIG. 3 is a simplified perspective view illustrating methods for manufacturing the 2D net of FIG. 1A;

FIGS. 4A and 4B are simplified, enlarged side views illustrating methods of manufacture in accordance with principles of the present disclosure;

FIG. 4C is a graph of Raman spectroscopy of 2D GO before metal deposition and 3D GO after self-folding and etching of the production layer;

FIG. 5A is a graph of deconvolutions of the C1s peaks of X-ray photoelectron spectroscopy (XPS) spectra of GO sheets described in the Examples section;

FIG. 5B is a graph of deconvolutions of the C1s peaks of XPS spectra of RGO sheets described in the Examples section;

FIG. 6 is a schematic illustration of a fabrication process of 2D GO membranes described in the Examples section;

FIG. 7 is schematically illustrates a fabrication process described in the Examples section along with corresponding optical images;

FIG. 8 are optical images illustrating transparency change of a 3D microstructure with 10 nm thick GO membranes of the Examples section;

FIG. 9 is a graph of optical transparency changes of the structures described in the Examples section;

FIG. 10 is a graph of number of GO layers versus their corresponding highest transparency changes in 3D microstructures described in the Examples section;

FIG. 11 is a graph of simulated transmission spectrum of a 3D GO structure with 10 layers of GO membranes for wet and dry cases described in the Examples section; and

FIG. 12 are simulations showing light scatter field inside of a 3D cubic structure (5×5×5 μm³) with different environments.

### DETAILED DESCRIPTION

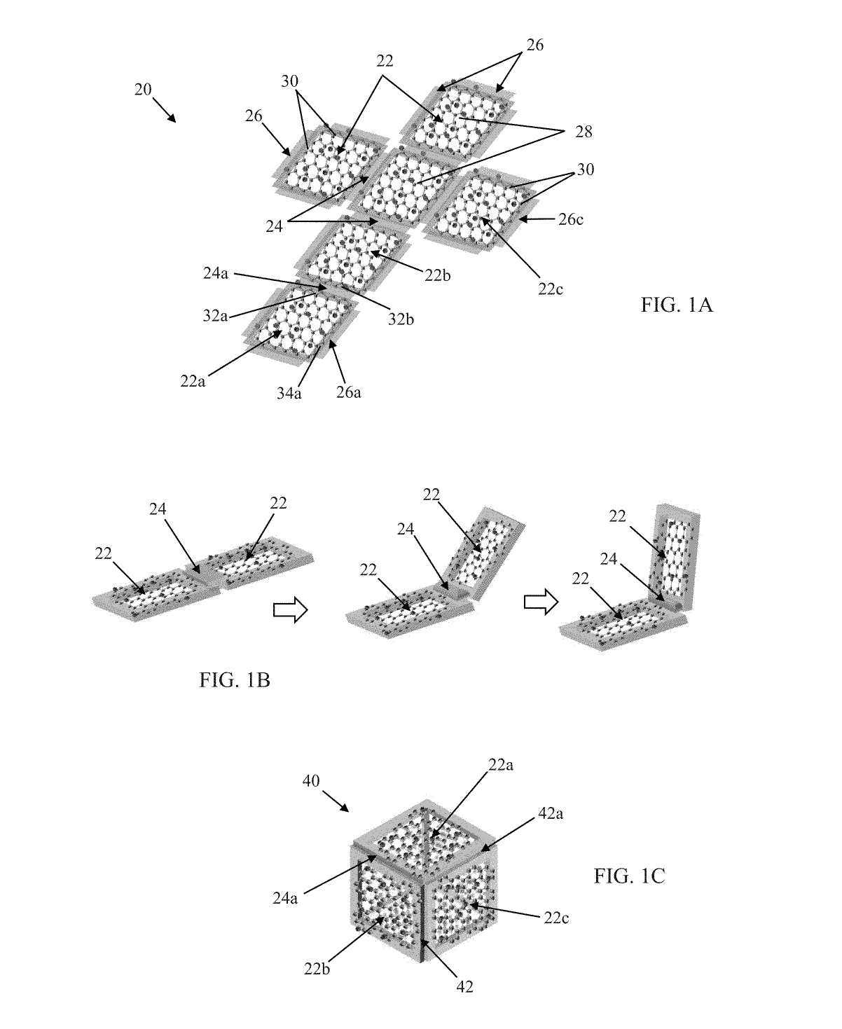

Aspects of the present disclosure are directed toward microscale, free-standing, 3D graphene-based structures and methods of manufacture. In some embodiments, an origami-like self-folding manufacturing approach is employed. For example, FIG. 1A illustrates a 2D net 20 from which a 3D microscale polyhedral (e.g., cubic) graphene-based structure can be generated. The 2D net 20 includes a plurality of microscale panels 22, hinges 24, and optional joint structures 26. Each of the panels 22 includes a graphene-based (e.g., GO) membrane 28 and a frame 30. Exemplary constructions of the graphene-based membrane 28 and the frame 30 are provided below. In general terms, the frame 30 physically supports the corresponding graphene-based membrane 28 and can be formed of various materials, such as metal (e.g., nickel), polymer, etc. Respective ones of the hinges 24 extend between and interconnect opposing edges of immediately adjacent ones of the panels 22 in the array of the 2D net 20. A material of each of the hinges 24 is selected to exhibit desired properties when subjected to an environmental changes, such as in the presence of heat (e.g., molten, surface tension force), and in some embodiments is solder (Pb—Sn). As initially provided in the form of the 2D net 20, the panels 22 are arranged in an array conducive to folding into a 3D polyhedral shape, with facing edges of immediately adjacent ones of the panels 22 being connected to one another by a corresponding one of the hinges 24. Stated otherwise, in the 2D net array, various panels 22 are arranged side-by-side or edge-to-edge; one of the hinges 24 extends between and interconnects the corresponding edges thereof. For example, first and second panels 22a, 22b are identified in FIG. 1A. In the array, the first panel 22a is immediately adjacent the second panel 22b, with a first edge 32a (referenced generally) of the first panel 22a facing or immediately proximate a first edge 32b of the second panel 22b. The first and second panels 22a, 22b are interconnected by a hinge 24a that extends between the first edges 32a, 32b. Other panel edges in the array of the 2D net 20 are free or not otherwise directly connected to another panel by a hinge. For example, a second edge 34a of the first panel 22a identified in FIG. 1A is not directly connected to a separate panel in the 2D net 20 state. In some embodiments, a joint structure 26 is provided at one or more (including all) of the panel free edges. Where provided, the joint structure 26 projects beyond the face of the corresponding panel 22 (e.g., FIG. 1A identifies joint structure 26a that is applied to the first panel 22a at the second edge 34a). A material of each of the joint structures 26 can be identical to that of the hinges 24 (e.g., solder) for reasons made clear below.

In some embodiments, the 2D net 20 is configured such that when the 2D net 20 is subjected to heat, the molten hinges 24 generate a surface tension force and causes the panels 22 to self-fold up into a 3D microscale structure. For example, FIG. 1B schematically depicts self-folding of the hinge 24 and two of the panels 22 when the hinge 24 is subjected to heat. FIG. 1C illustrates a 3D graphene-based microstructure 40 resulting from origami-like self-folding of the 2D net 20. As a point of reference, and with additional reference to FIG. 1A, where provided, various ones of the joint structures 26 are brought into contact with one another and fuse upon self-folding of the 2D net 20, resulting in a completed joint 42 at a corresponding edge of the 3D microstructure 40. For example, the first joint structure 26a is identified with the first panel 22a in FIG. 1A, as is a first joint structure 26c provided with a third panel 22c. The first-third panels 22a-22c are again labeled in FIG. 1C, along with the hinge 24a. With cross-reference between FIGS. 1A and 1C, one completed joint 42a of the 3D microscale structure 40 is generated by the first joint structure 26a of the first panel 22a and the first joint structure 26c of the third panel 22c upon completion of the self-folding operation.

The 2D net and resultant 3D microstructures of the present disclosure can assume a wide variety of other shapes, such as any polyhedral shape, and are not limited to the cubic shape of FIG. 1B.

Regardless of an exact shape of the 3D microstructure 40, each of the graphene-based (e.g., GO) membranes 28 can include a plurality of 2D graphene-based layers or sheets (e.g., a plurality of 2D GO layers or sheets). For example, each membrane 28 can consist of two or more 2D graphene-based (e.g., GO) layers, for example ten, twenty, forty, etc., 2D graphene-based layers. In some embodiments of the present disclosure, the number of 2D graphene-based layers provided with each of the membranes 28 and/or a spacing or gap between individual layers of each of the membranes 28 is selected or “tuned” to provide the resultant 3D microstructure 40 with desired optical characteristics appropriate for an intended end use. In this regard, with the multilayer construction, the graphene-based membranes 28 can be permeable, and exhibit differing optical properties (e.g., transparency) in the presence (or absence) of various liquids (e.g., liquid can vary the gap between individual layers of the graphene-based membrane 28); where the intended end use entails an environment with expected presence of liquid (e.g., humidity (such as water)), the graphene-based membranes 28 can be “tuned” to exhibit certain or pre-determined optical properties as a function of a change in the presence of liquid in the end use environment.

With the above in mind, and regardless of the exact method of manufacture and shape of the 3D graphene-based microstructure 40, other aspects of the present disclosure are directed toward 3D graphene-based microstructures with tunable optical features or properties. As a point of reference, the reflectance of a 2D GO multilayer structure (or membrane) has been found to produce periodic changes as the overall GO thickness (or number of layers) increases due to changing light interference as light passes through the GO layers. It is also known that forming multiple faces with different angles on a crystal greatly affect the 3D structure's brilliance, which leads to different spectral colors and luminousness like a rose cut diamond. With some 3D graphene-based microstructures 40 of the present disclosure, 2D graphene-based (e.g., GO) multilayer structures are used as faces (i.e., as the membranes 28) and form a 3D polyhedron structure, the 3D graphene-based microstructure can allow for multiple optical paths like a diamond; a feature which may greatly enhance the effect of changes in the optical properties of the 3D graphene-based microstructure 40. In addition, the presence or absence of water between the graphene-based (e.g., GO) layers comprising an individual membrane 28 can impact the optical paths (i.e., reflections and transparency) through the tuned structure and, hence, the overall optical characteristics. For example, some embodiments of the present disclosure utilize multilayer 2D GO for each of the membranes 28, and the 3D GO microstructures is configured to exhibit increasing transparency in the presence of liquid (e.g., water) and decreasing transparency (e.g., approaching opaque) as the level or amount of liquid in an environment of the 3D microstructure decreases. Unlike pristine graphene, oxygen functional groups in GO allow for the formation of multiple layers. The resultant, multilayer GO membrane 28 is water (or other liquid) permeable, with the space between layers available to be filled with water molecules; optical properties of the GO membrane 28 changes as a function of the presence (or absence) of these water molecules (or other liquid molecules) in the interlayer space.

In some embodiments, tuning of the 3D graphene-based microstructures of the present disclosure incorporates a combination of the water permeable nature of 2D GO membranes and a 3D hollow structure.

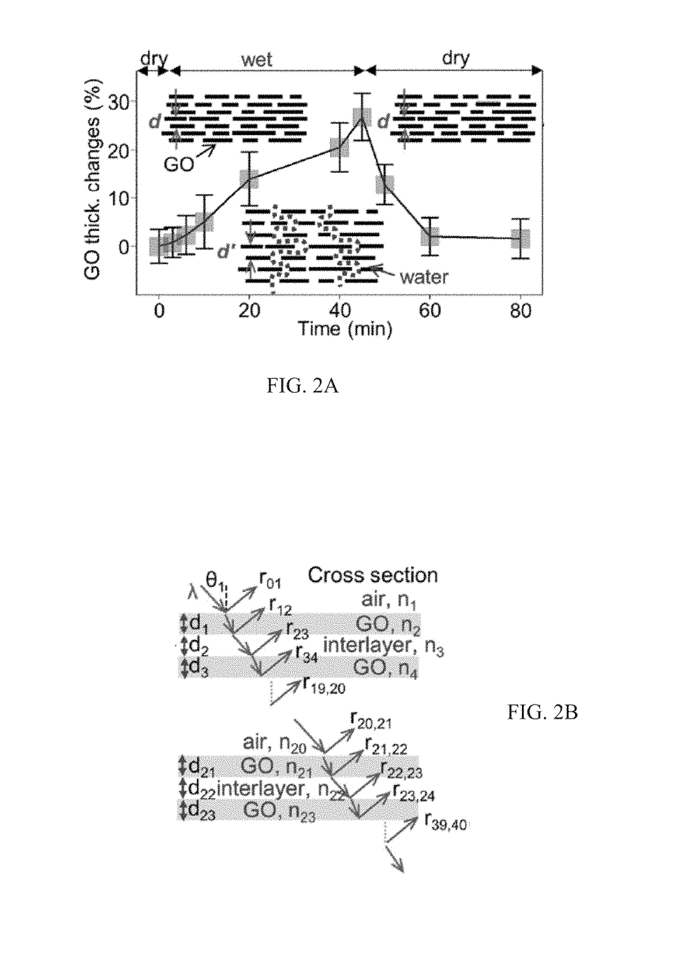

Origins of the tunable optical transparency features of the 3D graphene-based 3D microstructures of the present disclosure can be further understood or characterized in the context of interactions with water. For example, and with reference to FIGS. 2A-2C, water permeability can first be considered, more specifically, the effect of insertion/removal of water between GO layers. GO contains isolated sp² graphene domains surrounded by a continuous matrix of a sp³ network, which is comprised of oxygen functional groups such as hydroxyl, epoxy, and carboxyl. These functional groups allow for the multiple layer structure of the GO membrane with approximately 0.6-1 nm interspacing (d) between GO layers as schematically reflected in FIG. 2A. In a previous study, a freestanding GO multilayer structure showed water permeation properties where the water was inserted between the GO layers. FIG. 2A reflects that after water was filled or absorbed between GO layers, a new interspacing (d′) increased by Δd of approximately 0.3 nm from the original interspacing (d). The changes to the interspacing are reversible as the liquid dries. In order to confirm such an expansion of the interlayer distance (or variation of GO membrane thickness due to the insertion/removal of water) in the GO membranes of the present disclosure, GO membrane thickness was directly measured over time in dry-wet-dry states (air-water-air sequence) using a thickness profiler and are plotted in FIG. 2A. This experiment was done with 250 nm thick GO membranes on a Cu substrate; hence, the time taken is longer compared to the free-standing 10 nm thick GO membranes. The thickness of the GO membranes gradually increases from approximately 0% to approximately 26% in water and returns back to its initial thickness as the water dries out. This observation indicates that the interlayer distance increases by roughly Δd of approximately 0.26 nm from approximately 0.6 nm in water as suggested in a previous study. Therefore, and without being bound by any particular theory, the inventors of the present disclosure surmise that these interactions will lead to a variation in the optical property as the environment changes such as when the structure is exposed to air or liquid water.

With incident light, the total amplitude of reflected light off and back out of a thin film can be expressed in terms of two components: the amplitude of the light reflected at the interfaces and the phase changes as light traverses each layer of the multilayered thin film. The reflected light from the interface ij between the adjacent layers i and j is given by:

rᵢⱼ=|rᵢⱼ|exp[−2(δᵢ+δⱼ)] (1)

The amplitude of reflection is |rᵢⱼ|=[(nᵢ−nⱼ)/(nᵢ+nⱼ)]. The phase change of each layer is:

δᵢ=2πnᵢdᵢ cos θᵢ/λ (2)

where dᵢ is the thickness of the layer, nᵢ is the refractive index of the layer, θᵢ is the angle of refraction, and λ is the wavelength of incident light. As illustrated in FIG. 2B, in the case of 2D GO membranes, the light will be reflected at distinct interfaces: (i) between the outside of the GO membranes (or air) and the 1^{st} GO layer, r₀₁; (ii) between the 1^{st} layer and the interlayer spacing, r₁₂; (iii) between the interlayer spacing and the 2^{nd} layer, r₂₃; (iv) between the 2^{nd} GO layer and the interlayer spacing, and so forth; and (v) between the last layer and the outside of the GO membrane, r_{19,20}. For example, in the case of a GO membrane having approximately 10 layers of GO, a total of approximately 20 interfaces are expected. The total reflected light from a 2D GO membrane (r_{2D Go}) can be expressed as:

r_{2D GO}≈|r₀₁|+|r₁₂|exp(−2iδ₁)+|r₂₃|exp[−2i(δ₁+δ₂)]+|r₃₄|exp [−2i(δ₁+δ₂+δ₃)]+ . . . +|r_{19,20}|exp[−2i(δ₁+ . . . +δ₁₉)] (3)

Based on these relations, one can expect that when the membranes are in air versus in water, the refractive index and film thickness of interlayer spacing will be different (i.e., n₃ and d₂ in FIG. 2B). Hence, the total amount of reflections is different when the membranes are in air and in water.

A similar phenomenon has been observed in reflectin (a protein found in a squid) multilayer structures. As a reflectin thin film thickness increases due to water absorption, the refractive index decreases; resulting in changes in the reflectance of the films. These same variations occur in 2D GO membranes (and other graphene-based membranes) of the present disclosure, and result in transparency changes (e,g., ΔT* of approximately 11%), where the transparency of 2D GO in water is higher than in dry state; similar to oil saturated paper versus dry paper. Although this model explains changes in thickness and reflections of 2D GO membranes when the structure is exposed to different substances (e.g. gas or liquid water), this does not fully explain the dramatic tunable optical transparency (e.g., ΔT* approximately 57%) observed with some of the 3D graphene-based microstructures of the present disclosure. Transparency changes of a 3D enclosed graphene-based (e.g., GO) cube can be approximately 5 times larger than that of an open 2D graphene-based membrane. To elucidate the origin of the dramatic 3D tunable optical property, multiple reflections induced by the effect of 3D geometry can also be considered.

For a 3D object with a layered graphene-based membrane construction, multiple reflections or changes in light propagation inside the 3D micro box are expected where the light is transmitted through multiple faces (membranes) and some of the light is reflected inside the micro cubic box (internal reflections) as in the case of a rose cut diamond. This effect is schematically illustrated in FIG. 2C. Therefore, the additional light reflection interfaces, as well as its enclosed nature, can be considered. As seen in FIG. 2B, in the cross-section of the cube, there are approximately 40 types of interfaces (where each membrane consists of 10 layers): (i) approximately 20 interfaces from the top GO membrane, (ii) approximately 20 interfaces from the bottom GO membrane. In addition, since this is a closed structure, some of the light is reflected from the GO membranes placed on the sides of the cube (rᵢₙₜₑᵣₙₐₗ) (in FIG. 2C, only incident light on one face of the cube is shown) resulting in internal reflection, which also affects this unique property. In this case, the total reflected light from the 3D GO cube (r_{3D Go}) is as follows:

r_{3D GO}≈r_{2D GO(top)}+r_{2D GO(bottom)}+|rᵢₙₜₑᵣₙₐₗ|exp[−2i(δₙ)] (4)

where r_{2D GO(top)} and r_{2D GO(bottom)} are the total reflectance of the top and bottom sides of the cubes, and rᵢₙₜₑᵣₙₐₗ and δᵢₙₜₑᵣₙₐₗ are the amplitude and the phase change of the reflections from the inside of the cubic box, respectively. This relation indicates that the variation of refractive index and thickness of the interlayer spacing in 3D GO (or other 3D graphene-based microstructure of the present disclosure) by environmental changes has a larger impact on the total reflection compared to that of a 2D GO; resulting in dramatic optical transparency changes in a 3D GO microstructure.

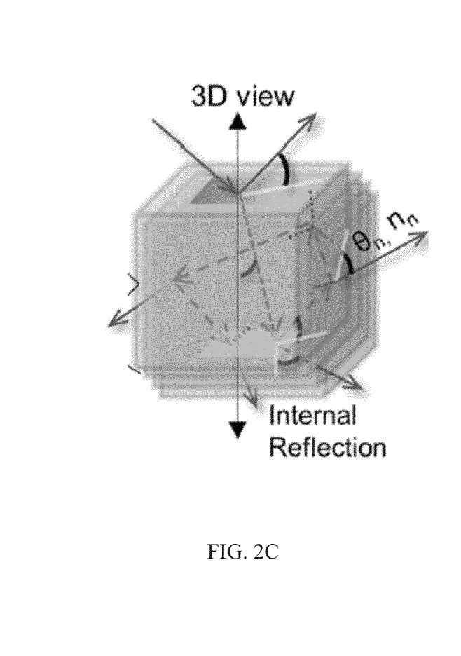

Returning to FIGS. 1A-1C, to better ensure that the optical properties or characteristics described above are achieved, fabrication methods of the present disclosure are configured to retain a desired or designed structure (e.g., number of layers) of the membranes 28 from initial formation as part of the 2D net 20 to final construction or transition to the 3D graphene-based microstructure 40 (e.g., the origami-inspired self-folding process described above). In some non-limiting embodiments, the graphene-based membranes 28 can be synthesized via Hummers method and can contain a carbon sp² fraction, for example on the order of approximately 55% with GO materials. To define the 2D net 20 of multilayered graphene-based (e.g., GO) membranes 28, the graphene-based material can be spun on a photoresist that has been patterned on a silicon (Si) wafer or other sacrificial layer 50 as generally illustrated in FIG. 3 and then the unwanted portions of the GO layer are removed by a lift-off process with flood exposure. Details of some non-limiting examples of the patterning and lift-off with flood exposure processes of the present disclosure are provided in the Examples section below. The thickness of each layer can be controlled by the number of spinning processes performed. For example, thickness of a GO layer is approximately 3.3 nm per spin at 1000 rpm. In some embodiments, the frames 30 and the hinges 24 are formed with the array of graphene-based membranes 28 prior to lift-off from the sacrificial layer 50. For example, the frames 30 can be formed onto the membranes 28 using known techniques (e.g., e.g., standard lithography followed by electrodeposition of the frame material (e.g., nickel)). The hinges 24 can similarly be formed over the so-generated frames 30 (a second lithography followed by electrodeposition of the hinge material (e.g., solder)). The frame 30 physically support the corresponding graphene-based membrane 28 that is otherwise thin and flexible (e.g., thickness on the order of 10-100 nm and area on the order of 150×150 μm² in some embodiments). The frames 30 also offer easy control of the size and shape of the resultant 3D structures. The hinges 24 generate surface tension force and fold up the 2D net 20, resulting in a hollow, microscale (e.g., 200 μm-sized), 3D graphene-based microstructure 40 (FIG. 1C) when the hinges 24 are heated at a melting temperature (e.g., approximately 150° C. where the hinges 24 are formed of solder in some embodiments) as described above.

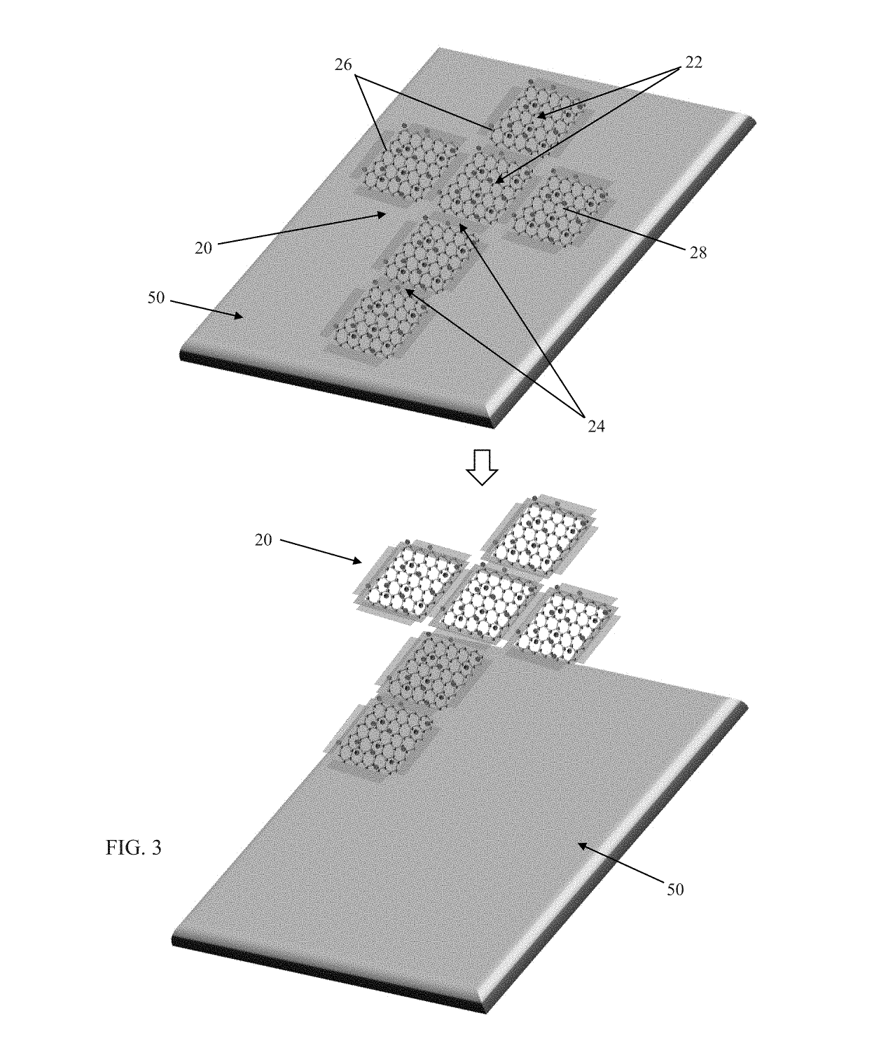

During the self-folding process, the optional heating process induces stress on the graphene-based membranes 28. To avoid possible delamination of the membrane 28 from the corresponding frame 30, some methods of the present disclosure insert or sandwich the graphene-based membrane 28 between first and second thin metal films or protection layers 60, 62 as reflected by FIG. 4A. With the optional sandwich structure of FIG. 4A, the protection layers 60, 62 protect and maintain the structural integrity of the graphene-based membrane 28. The optional sandwich structure of FIG. 4A also allows retention of unique intrinsic properties of graphene-based material (e.g., GO) because the membranes 28 are shielded from chemical and physical attacks which could occur during the fabrication processes prior to self-folding. In some embodiments, the first and second protection layers 60, 62 can have identical constructions, and can comprise two or more sub-layers. For example, the first protection layer 60 can consist of a first sub-layer 64 deposited onto the sacrificial body or layer 50, and a second sub-layer 66 deposited onto the first sub-layer 64 (e.g., the first sub-layer 64 can serve as an adhesion layer, and the second sub-layer 66 can serve as a seed layer). The first sub-layer 64 can be chromium (Cr) and the second sub-layer 66 can be copper (Cu). The graphene-based membrane 28 is then formed over the first protection layer 60. The second protection layer 62 is then formed over the membrane 28, and can comprise a first sub-layer 68 (e.g., Cr) and a second sub-layer 70 (e.g., Cu) as described above. The metal frame 30 is formed over the second protection layer 62, followed by formation of the hinge 24 (and/or joint structure 26). FIG. 4B reflects that the protection layers 60, 62 protect the membrane 28 after lift off from the sacrificial layer 50. After assembly (folding), exposed portions of the protection layers 60, 62 can be selectively etched by a wet etching process.

It has surprisingly been found that the above methods maintain desired properties (e.g., optical characteristics) of the membranes 28 throughout the fabrication and self-folding processes. As a point of reference, Raman spectra were obtained of pristine 2D GO spun on a Si substrate and of 3D self-folded GO microstructures manufactured as described above (i.e., with the GO membrane sandwiched between Cr/Cu protection layers) and are presented in FIG. 4C. The pristine GO membranes (plot line 80) and the GO membranes after self-folding and etching of the protection layers (plot line 82) show D, G, and 2D bands at the same positions of Raman shifts. This observation indicates that the GO membrane retains its intrinsic properties, such as tunability, and no intercalation process is induced during the fabrication process, demonstrating the robustness of the methods of the present disclosure.

3D polyhedral graphene-based microstructures can be generated by the origami-inspired self-folding methods of the present disclosure. These and other approaches allow for the fabrication of a hollow 3D microstructure configured with 2D materials GO, which incorporates the permeation-driven tunability of multilayered 2D materials into 3D geometry. The 3D polyhedral GO structures show higher optical sensitivity to environmental conditions, resulting from the combined properties of the 3D hollow structure and the water-permeable multilayer windows that affect the optical paths. In some embodiments, the tunable optical properties can be utilized for the development of a dynamic controller of transmitted solar radiation or a new camouflage technique, immediately responding to environment changes without external energy input. Other end use applications of the 3D graphene-based microstructures of the present disclosure include low cost solar control technology, providing a new physical concept for a new generation smart window (green energy). Alternatively, the 3D graphene-based microstructures of the present disclosure can be employed in various environmental response applications, such as sensors, detectors or lens, by using optical reaction systems in specific conditions such as chemical and biological (or bio chemical) hazards. For example, the 3D graphene-based microstructures of the present disclosure can be used as or as part of a gas detector/sensor (e.g., detecting or sensing NO₂, H₂O, NH₃, CO, etc.); a bio sensor (e.g., DNA (or toxic bio hazard), for specific targeted objects, the membranes can be modified (i.e., nanoscale porous). Alternatively, the 3D graphene-based microstructures of the present disclosure can be used with separation or filtration technology, such as water desalination, chiral separation (e.g., drug or medicine separation), etc. Alternatively, the 3D graphene-based microstructures of the present disclosure can be used with air pollutants (e.g., fire alarm) and weather checking (e.g., global warming) system with communication with satellite or via optical system. Alternatively, the 3D graphene-based microstructures of the present disclosure can be used with wireless sensing in 3D media such as brain, detection of bacteria or viruses by frequency shift, etc. Alternatively, the 3D graphene-based microstructures of the present disclosure can be used with other systems requiring very light weight sensors, such as flying sensors (similar to a scape balloon sensor), etc. Moreover, additional physical and chemical properties of the hollow 3D GO microstructure may exist and lead to breakthrough technologies and state-of-the-art applications in diverse science and engineering fields for a new generation of 3D-configured, 2D material-based devices.

Embodiments and advantages of features of the present disclosure are further illustrated by the following non-limiting examples, but the particular materials and amounts thereof recited in these examples, as well as other conditions and details, should not be construed to unduly limit the scope of the present disclosure.

### EXAMPLES

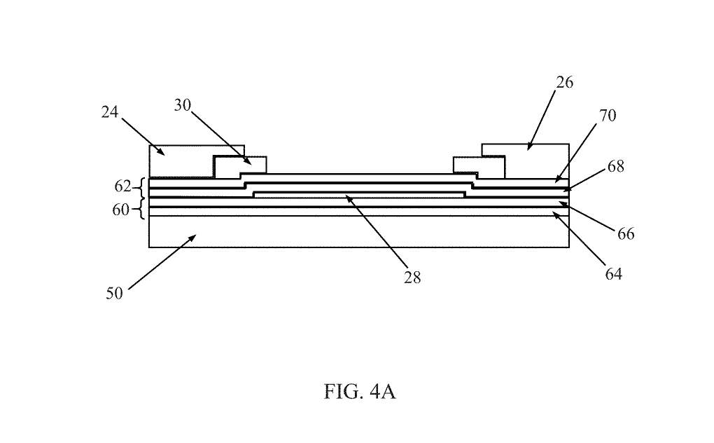

Example 3D graphene-based microstructures in accordance with principles of the present disclosure were prepared as follows. Individual GO sheets in powder form were obtained by a modified Hummers method. 15 mg of GO powder was added to a flask containing 15 mL of deionized (DI) water. Then, the GO solution was stirred in a water bath for 24 hours. In order to reduce oxygen functional groups of GO, or to make reduced graphene oxide (RGO), hydrazine hydrate reduction methods were used. 15 mg/ml of GO dispersion in water was mixed with 30 μl of 5% ammonia aqueous solution and 15 μl of hydrazine solution. Then, the GO solution was put in a water bath (approximately 95° C.) for 1 hour and then cooled to room temperature. X-ray photoelectron spectroscopy (XPS) was used to characterize the amount of oxygen functional groups in (or sp² fraction of) GO and RGO as shown in FIGS. 5A (GO) and 5B (RGO). The four deconvoluted peaks indicate the deoxygenated graphene (C—C) at approximately 284.5 eV, oxygen-containing functional groups for hydroxyl (C—OH) at ˜286.0 eV, carbonyl (C═O) at approximately 287.0 eV, and carboxyl acid (O═C—OH) at approximately 288.5 eV. The C—C peak refers to the amount of sp² carbon components and the oxygen-containing functional groups refer to the amount of sp^{a}-hybridized carbon. The carbon sp² fraction was calculated by taking the ratio of the integrated peak areas corresponding to the C—C peak to the total area under the C1s spectrum. The carbon sp² fractions are 55 and 75% for GO and RGO, respectively. XPS experiments were conducted using a Surface Science Labs (SSX-100) spectrometer. For structural characterization of 2D and 3D GO structures, Raman spectroscopy was performed using an Apha300R Raman spectrometer composed of a laser (Ar ion laser 514.5 nm).

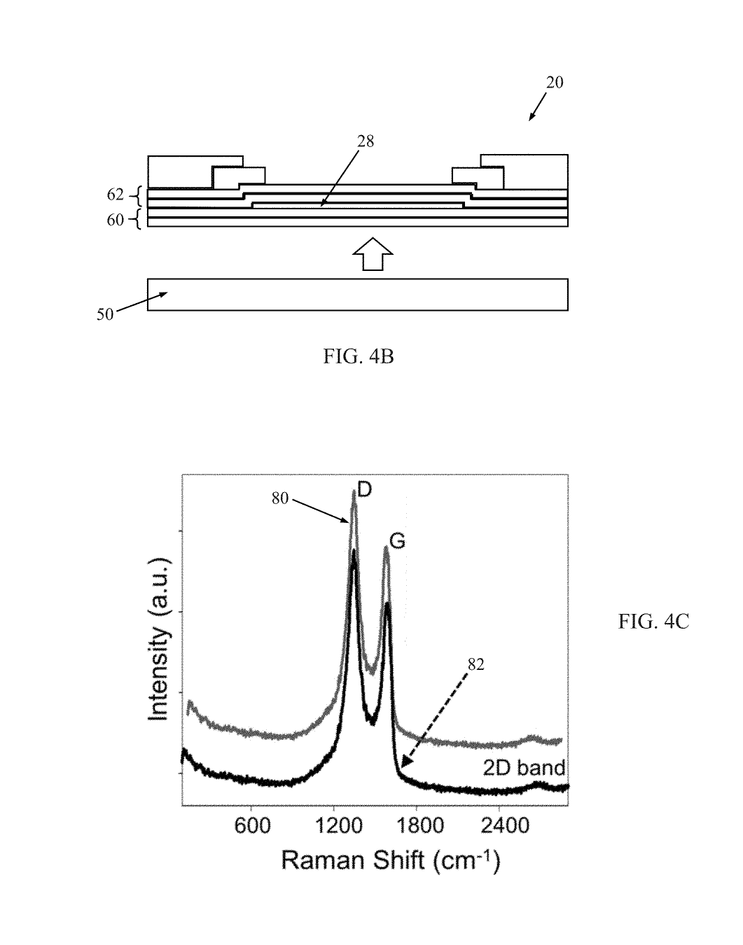

The so-formed GO sheets were then fabricated into 2D GO patterns using a lift-off with flood exposure process. In general, chemical wet etching or plasma etching are used to pattern 2D GO membranes. However, this process was not usable with the Examples because sacrificial layers (i.e., poly(methyl methacrylate) (PMMA)), which may be damaged by solvent, were used to release the 2D nets from a substrate. To overcome this challenge, a lift-off process via flood exposure was used. The lift-off process did not require the use of a chemical etchant and/or plasma. Instead, it employed flood exposure before GO spin coating, and the unwanted area was dissolved in a developer. The schematics of the process are shown in FIG. 6. A positive photoresist is spin-coated onto the sacrificial layer and patterned with desired features followed by a standard development process. The lateral dimension of each of the GO membranes was 150 μm×150 μm. A flood exposure of the entire substrate was performed without a mask. The flood exposure had no effect on the patterned area; however, it exposed the remaining area, which could then be removed by the developer. GO was spin-coated on top of the sacrificial layer. By immersing it into the developer, unwanted GO sheets were removed. With this method, different thicknesses of the GO and RGO membranes were made. The thicknesses of the GO layers were easily controlled by the number of a spinning process (3.3 nm per spin at 1000 rpm for 60 sec). Approximately 10 (approximately 10 nm thick), approximately 20 (approximately 20 nm thick), and approximately 40 layers (approximately 40 nm thick) of GO membranes and approximately 10 layers of RGO membranes were realized on the sacrificial layer.

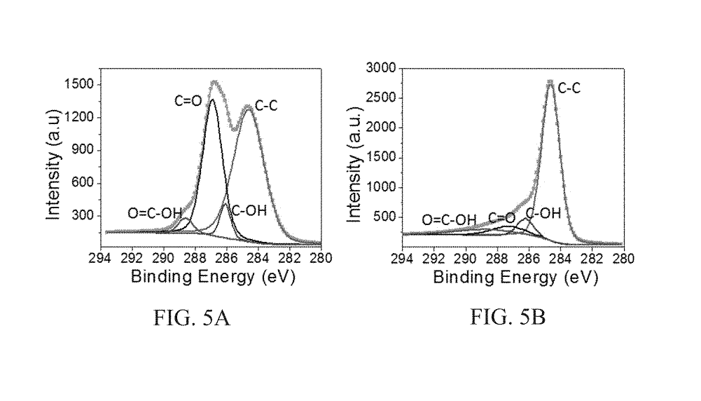

3D GO microstructures (microcubes) were then fabricated from the 2D GO layers. As a point of reference, FIG. 7 provides schematics and optical images of the fabrication process of the 3D GO microstructures (the scale bars are 200 μm). At first, a 1 μm thick PMMA sacrificial layer was deposited on a polished Si wafer. Cr (10 nm) and Cu (150 nm) layers were deposited using an e-beam evaporator. Prior to GO deposition, the window pattern was done by photolithography. A positive photoresist (Megaposit™ SPR™220, distributed by MicroChem Corp., Newton, Minn.) of 10 μm thickness was spin-coated (1700 rpm for 60 sec) on top of the prefabricated substrate followed by baking at 115° C. for 60 sec and a wait time of 3 hours. The sample was UV exposed on a contact mask aligner for 80 sec and developed for 90 sec in a developer solution (AZ® Developer from AZ Electronic Materials, Charlotte NC, a division of Merck KGaA). The dimension of each face of the window was approximately 150×150 μm² (width×length). Then, a flood exposure process was followed to lift-off unwanted area. Then, the solution-processable GO was spin coated at 1000 rpm for 60 sec (performed 3 times for approximately 10 layers, 5 times for approximately 20 layers, and 10 times for approximately 40 layers of GO membranes). Dipping in the AZ® developer allowed lift-off of unwanted GO on the substrate. On top of GO membranes, another layer of Cr (10 nm) and Cu (150 nm) were deposited prior to electrodeposition of frame and hinge. The cubic frame panels were then patterned using standard lithography followed by electrode deposition of Ni (approximately 10 μm). In order to make the hinge pattern, another lithography was performed with approximately 20 μm thick solder (Pb—Sn). The Cu/Cr layers were dissolved by appropriate etchants. An ammonium persulfate etchant (APS-100 Copper Etchant from Transene Company, Inc., Danvers, Mass.) was used to dissolve exposed Cu surface area. A hydrochloric acid etchant (Chromium Etchant CRE-473 from Transene Company, Inc., Danvers, Mass.) was used to dissolve exposed Cr surface area. To release the 2D net structures, the PMMA was dissolved by N-Methyl-2-pyrrolidone (NMP-based stripper from MicroChem Corp, Newton, Minn.). The released template was heated above the melting point of the hinge materials (200° C.) and assembled (folded) into the cubic shape followed by a rinsing process. Finally, the remaining Cr/Cu layer was removed by the same etchants used previously.

A numerical analysis of light propagation through the 2D GO and 3D GO microcubes of the Examples described above by using the 3D finite-difference time-domain (FDTD) method (Lumerical solution package). A 5-micrometer square for 2D and a 5-micrometer cubic box for 3D were established, with a planar wave of light incident from left to right towards the surface of the GO (for 3D, top of the cubes) with 45° tilting angle. A monitor was placed on top of the GO surface (for 3D, top of the cubes) to obtain the power of transmitted light. A non-uniform conformal mesh was applied, with a mesh size of 100 nm along the GO plane and 1 nm along the out-of-plane direction. Then, a larger scale three-dimensional model was set up to view the light distribution in the cubic defined by GO boundaries. Perfect matching layer (PML) boundary conditions were applied on all surfaces for both cases. The transmissions were collected with a plane-wave excitation source.

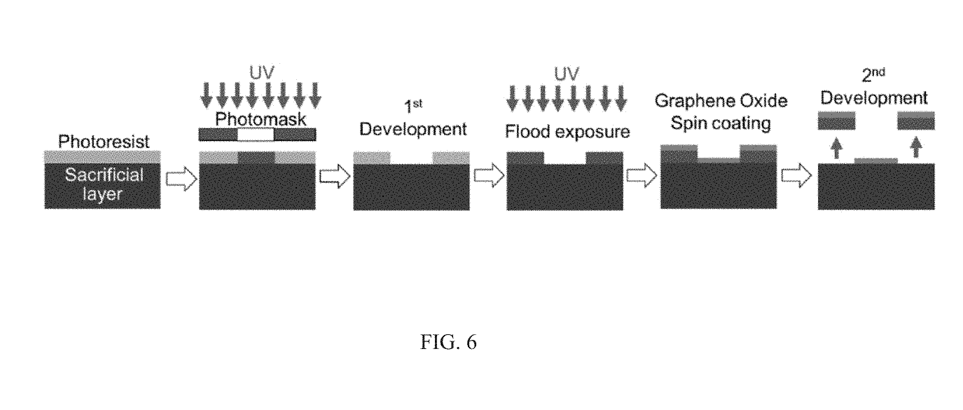

Testing was performed to evaluate a change in optical properties of the microstructures of the Examples section in the presence of water. With each test, to observe the optical transparency of a sample microstructure, two visible light sources (intensity of 50 mW/cm²) were directed toward the structure (at 45° and 135° angles) while a high resolution microscope monitored the 3D hollow structure. FIG. 8 provides a series of optical microscope snapshot images of a sample microstructure (cubic) having 10 nm thick (approximately 10 layers) GO membranes with carbon sp² fraction of approximately 55%. When the sample was soaked in water (wet), the GO membranes were highly transparent all around (left-most image in FIG. 8). However, as the water evaporated, the transparencies of all sides gradually decreased and the 3D GO membranes eventually became opaque. Notably, this observation was reproduced; that is, the transparency change of the 3D GO cubes is reversible and can be repeated. This unique tunable optical response was even observed at different incident light and microscope angles (e.g. top and side view) as well. Such behaviors were also seen when acetone and isopropyl alcohol (IPA) were used instead of water.

In order to conduct a quantitative analysis of these transparency changes, a commercial source was used and transparency profiles of the GO membranes in 3D microstructures of the Examples section were obtained every 10 seconds from wet to a dry state. Evaluated samples fabricated in accordance with the Examples section included: (i) 3D GO cubic microstructure with GO membranes each comprising approximately 10 layers; (ii) 3D GO cubic microstructure with GO membranes each comprising approximately 20 layers; (iii) 3D GO cubic microstructure with GO membranes each comprising approximately 40 layers; and (iv) 3D RGO cubic microstructure with RGO membranes each comprising approximately 10 layers. Similar, comparative testing was also performed for a 3D cubic microstructure having panels with aluminum oxide windows (in place of the graphene-based membranes) and a 2D GO net with GO membranes each comprising approximately 10 layers. The transparency changes (at the top side of the 3D structure) were calculated as:

ΔT(%)=[(T_{wet}−T_{dry})/T_{dry}]×100 (5)

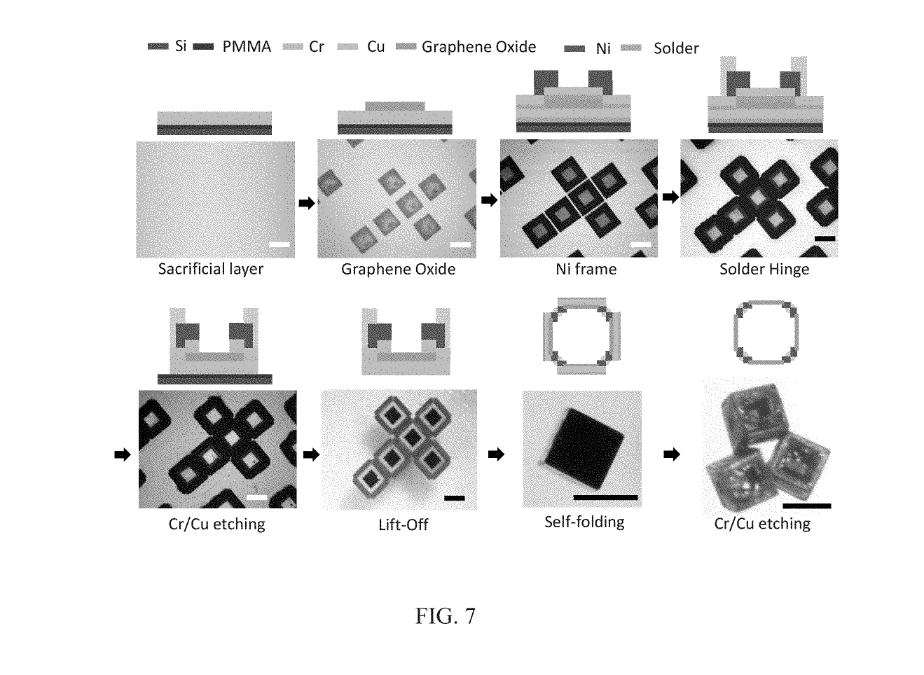

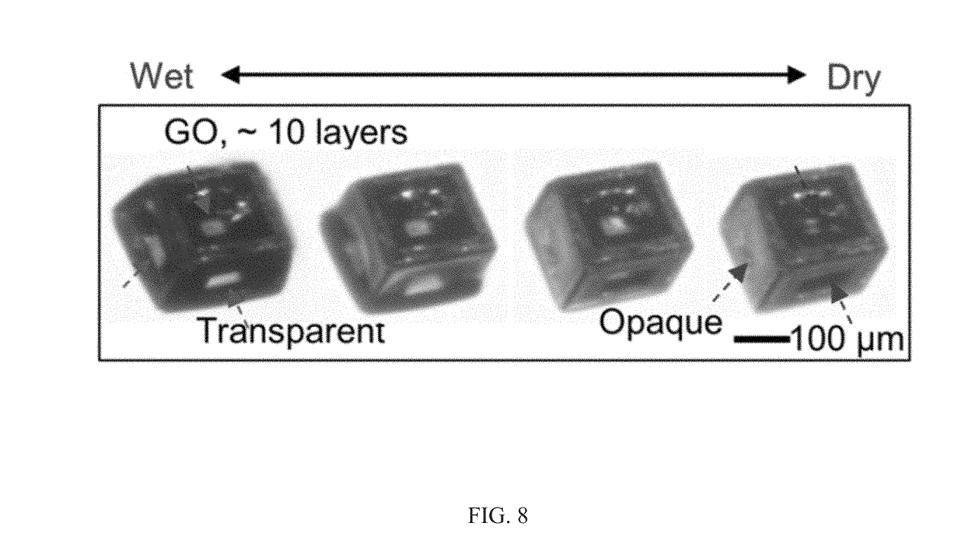

FIG. 9 reports the results of the quantitative transparency change testing. The highest transparency change (ΔT*) was found with the 3D GO cubic microstructure samples with GO membranes comprising approximately 10 layers (ΔT* of approximately 57%). For the 3D GO cubic microstructure samples with GO membranes comprising approximately 20 layers (i.e., GO membrane thickness of approximately 20 nm), such transparency changes were still observed, however, the transparency changes (ΔT* of approximately 27%) were not as high as that of the 3D cube with approximately 10 layers of GO membranes. With the 3D GO cubic microstructure samples with GO membranes comprising approximately 40 layers (i.e., GO membrane thickness of approximately 40 nm), considerable transparency changes were not observed as clearly (a ΔT* of less than 4.5%). FIG. 10 plots a comparison of the highest transparency change (ΔT*) for three GO samples. The 3D RGO cubic microstructure sample with approximately 10 layers of reduced graphene oxide (RGO) prepared by a hydrazine reduction method, which contained a sp² carbon fraction of approximately 75%, was opaque both in liquid and air or less than 4.2%).

In order to check the reliability of the experiment and the effects of the Ni frames and 3D structures without multilayer membranes, transparency changes of 3D cube with Al₂O₃ membranes (100 nm thick) were also characterized; the 3D cube with Al₂O₃ membranes showed almost no changes in transparency when transitioning between liquid and air. The experiment yielded a ΔT* of less than 2% as reported in FIG. 9. To confirm whether the optical transparency changes originate from the 2D GO membrane, 3D geometry, or a fusion of the 3D nature and the 2D GO properties of the structure, control experiments with 2D GO (an open structure) were conducted. As reported in FIG. 9, the approximately 10 layers of 2D GO membrane (i.e., GO membrane thickness of approximately 10 nm) with carbon sp² fraction of approximately 55% shows transparency under water just as in the 3D GO cubic microstructure sample; however, when the 2D sample (not completely enclosed structure) is in air, transparency of the 2D sample is retained unlike the enclosed 3D GO structure. For the 2D sample, ΔT* was found to be about 11%, which is about 5 times lower than that of the 3D GO cubic microstructure sample (with GO membranes comprising approximately 10 layers). These results showed that (i) transparency changes increase with decreases in thickness of GO membranes; (ii) with the same thickness of membrane, 3D GO shows higher transparency changes compared to that of 3D RGO; and (iii) an enclosed 3D GO structure shows a more dramatic tunable optical response compared with an open 2D GO structure.

Intrinsically, the optical transparency of GO decreases with increases in the number of GO layers (or thickness). Thus, the experimental results above reflect that the 3D GO cubic microstructure samples with thicker GO membranes exhibit less variation in transparency through the microstructure, leading to decreases in ΔT*. Moreover, in the case of the 3D RGO containing a sp² carbon fraction of approximately 75%, the interlayer space (d_{RGO} of approximately 0.36 nm) is smaller than that of GO (d_{GO} approximately 0.6-1 nm). Because of the narrow interlayer space, RGO is known to be impermeable to most gases and liquids, similar to how graphite behaves. Of course, a limited amount of water molecules can permeate through topological defects; however, it is a negligible amount. Such an impermeable property of RGO membranes may not allow changes in interspacing (Δd approximately 0), leading to no significant refraction index changes even though the environment changes. Therefore, there may be a lower possibility of transparency changes under water for the 3D RGO structure. Thus, the inventors of the present disclosure have surprisingly discovered that the optical transparency changes result from a combination of the water permeable nature of 2D GO membranes and the effect of the 3D hollow structure, both of which combine to induce novel optical properties.

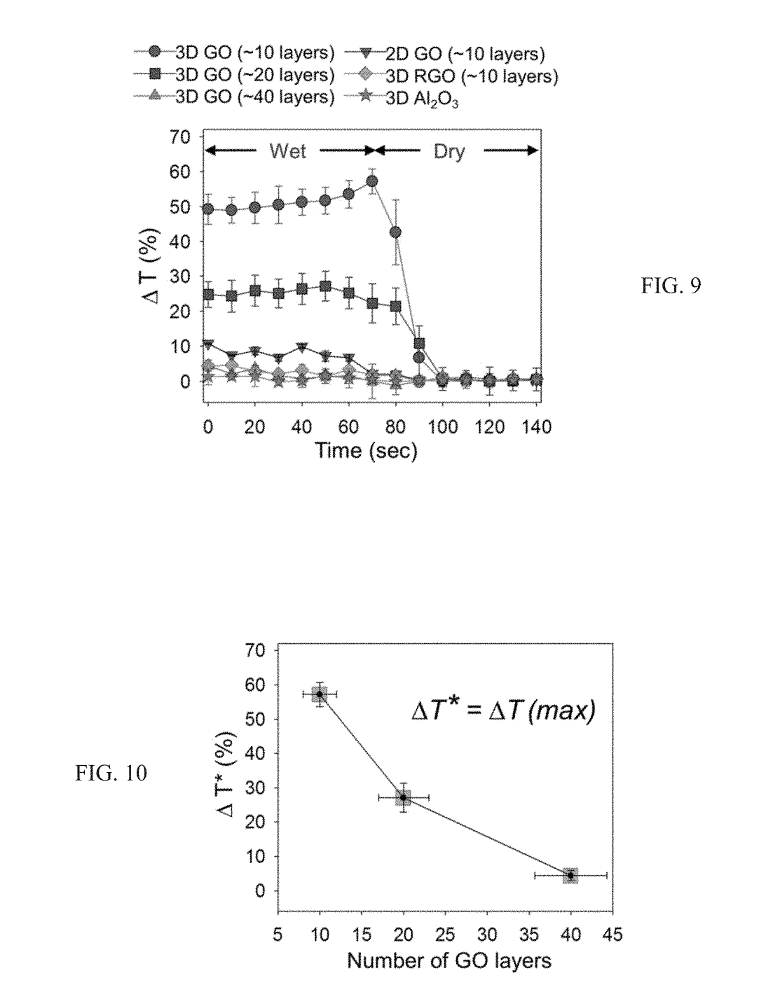

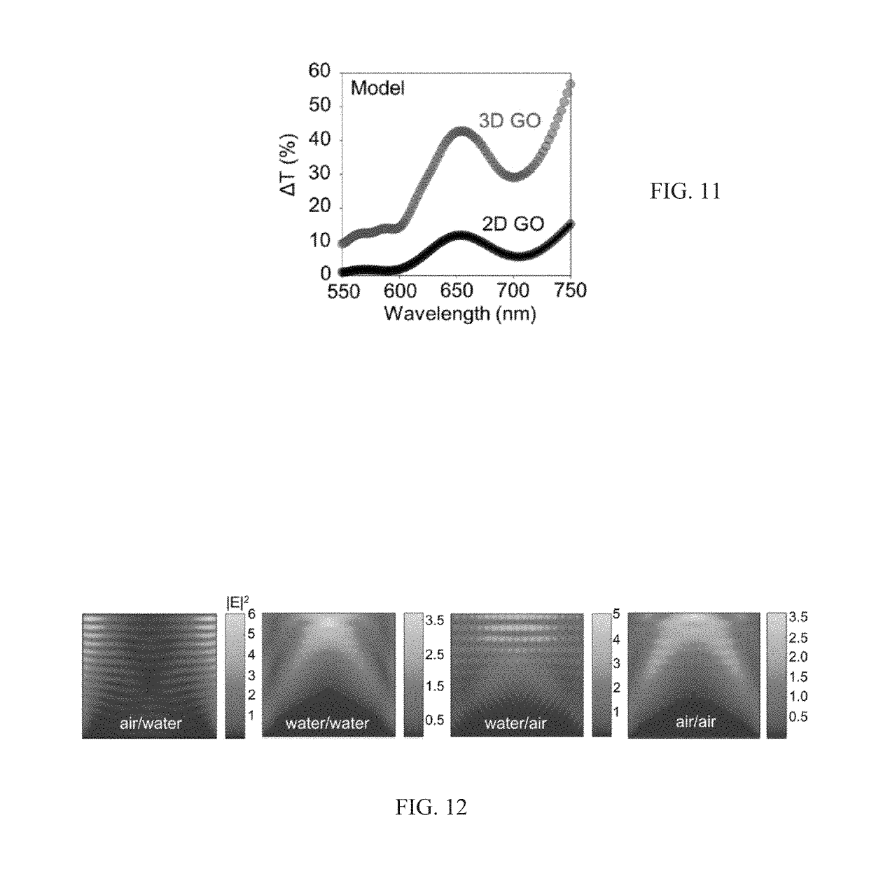

To further explain the modification of the optical spectrum by 3D graphene-based microstructures of the present disclosure, a 3D finite-difference time-domain (FDTD) simulation was conducted. The simulation was performed with 10 nm thick (approximately 10 layers) GO membranes for both 2D net (5×5 μm²) and 3D cubic (5×5×5 μm³, due to computational limitations, the simulation with a smaller-sized GO cube was performed) formats in the visible wavelength ranges with 45° incident angle to assess the qualitative understanding of the light propagation through the GO structure. This modeling analysis provides a qualitative understanding of the light propagation through GO membrane structure. As observed experimentally, the simulations showed that the transmission of GO in water (wet) is higher than that of in air (dry) for both 2D and 3D in the visible light wavelength ranges of 550-750 nm. In addition, a comparison of changes in transmission ΔT (%) of 3D GO to that of 2D GO was also performed. A plot of the results is provided in FIG. 11. The changes ΔT (%) in water and air for 3D GO cubic microstructures were found to be from approximately 10 to approximately 56%, and for 2D GO membrane from approximately 2 to approximately 15%, which is comparable to that of the experimental results. It has been also found that the light propagation inside of the cubes is strongly modified by environmental effects. FIG. 12 shows scattering field simulation profiles inside of the modeled 3D GO microstructure when the inside/outside of the cube is filled with air/water, water/water, water/air, and air/air at a 650 nm incident wavelength. The light propagation inside of the 3D structure is strongly responsive to the environment, which is the effect normally observed in optical micro/nanostructures in nature such as beetles Tmesisternus isabellae, morph butterflies, and multi-faced diamonds. Therefore, the 3D graphene-based microstructures of the present disclosure can allow for multiple optical paths, a feature that greatly enhances the light propagation inside of the structure. In addition, the presence or absence of water between and outside of the graphene-based (e.g., GO) layers affects the optical paths through the structure and hence, the overall optical characteristics.

Although the present disclosure has been described with reference to preferred embodiments, workers skilled in the art will recognize that changes can be made in form and detail without departing from the spirit and scope of the present disclosure.

What is claimed is:

1. A method of making a 3D graphene-based microstructure, the method comprising:
forming a 2D net including a plurality of panels and hinges, wherein each panel includes:
a frame,
a graphene-based membrane supported within the frame,
wherein the panels are connected to one another and arranged in an array, and further wherein a respective one of the hinges extends between and interconnects immediately adjacent ones of the panels within the array; and
heating the 2D net, wherein the step of heating includes each of the hinges self-folding to transition the 2D net into a 3D graphene-based microstructure.

2. The method of claim 1, wherein each of the graphene-based membranes comprises includes a plurality of graphene-based layers.

3. The method of claim 1, wherein each of the graphene-based membranes comprises a plurality of graphene oxide layers.

4. The method of claim 3, wherein the each of the graphene oxide layers are two dimensional sheets.

5. The method of claim 1, wherein the step of forming a 2D net includes spin coating a graphene-based solution over a sacrificial layer.

6. The method of claim 5, wherein the graphene-based solution is a graphene oxide solution, and wherein the step of forming a 2D net further includes generating each of the membranes to comprise a predetermined number of 2D graphene oxide layers by controlling the number of times the graphene oxide solution is spin coated over the sacrificial layer.

7. The method of claim 6, wherein the step of forming a 2D net further comprises:
determining a desired optical property of the 3D graphene-based microstructure; and
selecting the predetermined number of 2D graphene oxide layers based upon the determined desired optical property.

8. The method of claim 1, wherein the step of forming a 2D net further comprises:
depositing a first protection layer over a sacrificial layer; and
depositing a graphene-based solution over the first protection layer so as to define the membrane of each of the panels.

9. The method of claim 8, wherein the step of forming a 2D net further comprises:
lifting the 2D net off of the sacrificial layer.

10. The method of claim 8, wherein the step of forming a 2D net further comprises:
depositing a second protection layer over the deposited graphene-based solution.

11. The method of claim 10, wherein the step of forming a 2D net further comprises:
depositing a frame material over the second protection layer to define the frame of each of the panels.

12. The method of claim 11, wherein the step of forming a 2D net further comprises:
depositing a hinge material over a portion of the deposited frame material and a portion of the second protection layer to define the plurality of hinges.

13. The method of claim 12, further comprising removing exposed portions of the first and second protection layers prior to the step of heating the 2D net.

14. A 3D graphene-based microstructure comprising:
a plurality of panels each comprising:
a frame,
a graphene-based membrane supported by the frame,
wherein the panels are arranged relative to one another to define a polyhedral shape having an interior volume; and
a plurality of joints, wherein respective ones of the joints interconnect opposing edges of immediately adjacent ones of the panels in the polyhedral shape.

15. The 3D graphene-based microstructure of claim 14, wherein each of the graphene-based membranes comprises a plurality of graphene-based layers.

16. The 3D graphene-based microstructure of claim 14, wherein each of the graphene-based layers comprises graphene oxide.

17. The 3D graphene-based microstructure of claim 16, wherein each of the membranes comprises 10-40 graphene oxide layers.

18. The 3D graphene-based microstructure of claim 14, wherein each of the membranes is flat.

19. The 3D graphene-based microstructure of claim 14, wherein each of the membranes is configured exhibit a change in optical transparency in the presence of water.

20. The 3D graphene-based microstructure of claim 14, wherein each of the frames comprises nickel, and each of the joints comprises solder.
